(19) United States
(12) Patent Application Publication
(10) Pub. No.: US 2021/0118469 A1
(43) Pub. Date: Apr. 22, 2021

(54) OXIDE OR NITRIDE OVERLAYER FOR USE ON A DIAMOND-LIKE CARBON FILM

(71) Applicant: Western Digital Technologies, Inc., San Jose, CA (US)

(72) Inventors: Nattaporn Khamnualthong, Pathumthani (TH); Krisda Siangchaew, Nonthaburi (TH)

(21) Appl. No.: 16/659,473

(22) Filed: Oct. 21, 2019

(51) Int. Cl. G11B 5/73; G11B 5/84; G11B 5/72; C23C 14/06; C23C 28/04

(52) U.S. Cl. CPC G11B 5/7366; G11B 5/8408; G11B 5/72; G11B 5/653; C23C 28/046; C23C 28/042; C23C 14/0611

(57) ABSTRACT

Overlayers for coating diamond-like carbon (DLC) films are disclosed for use with DLC films employed on the sliders of hard disk drives, such as the sliders of heat assisted magnetic recording (HAMR) or energy assisted magnetic recording (EAMR) drives. In some illustrative examples, the overlayer is formed of an oxide, such as hafnium dioxide or tantalum pentoxide. A buffer layer formed, for example, of silicon nitride is interposed between the oxide overlayer and the DLC film. The oxide layer is provided to prevent oxidation of the DLC film during HAMR so as to maintain thermal stability of the DLC film and prevent a loss of optical transparency at the laser wavelengths of HAMR. The buffer layer is provided to prevent chemical mixing of the oxide overlayer and the DLC film. In other examples, an overlayer formed of silicon nitride is formed directly on the DLC film with no buffer layer.

### FIELD

The disclosure relates, in some aspects, to diamond-like carbon (DLC) films formed on devices such as the sliders of hard disk drives and to buffers and overlayers on the DLC film.

### INTRODUCTION

Diamond-like carbon (DLC) films may be formed, for example, on the sliders of hard disk drives (HDDs) or on other devices that benefit from an extremely hard and durable protective film or coating. Issues may arise related to the thermal stability and optical transparency of the DLC films, particularly when using an ultrathin DLC film on a heat assisted magnetic recording (HAMR) head or on other energy-assisted magnetic recording (EAMR) heads. Issues may also arise related to thermal oxidation of metal alloy substrates upon which ultrathin DLC films are formed, such as Ni—Fe slider components.

Aspects of the present disclosure are directed to addressing these or other issues.

### SUMMARY

The following presents a simplified summary of some aspects of the disclosure to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present various concepts of some aspects of the disclosure in a simplified form as a prelude to the more detailed description that is presented later.

One embodiment of this disclosure provides a structure for use in a disk drive where the structure includes: a substrate of a component of the disk drive; a diamond-like carbon (DLC) film on the substrate; a buffer layer on the DLC film; and an oxide layer on the buffer layer.

Another embodiment of the disclosure provides a method for forming a structure for use in a disk drive, the method including: providing a component of the disk drive, where the component comprises a substrate; forming a DLC film on the substrate; forming a buffer layer on the DLC film; and forming an oxide layer on the buffer layer.

Yet another embodiment of the disclosure provides a structure for use in a disk drive, where the structure includes: a substrate of a component of the disk drive; a DLC film on the substrate; and a silicon nitride layer on the DLC film.

Still another embodiment of the disclosure provides a method for forming a structure for use in a disk drive, the method including: providing a component of the disk drive, where the component comprises a substrate; forming a DLC film on the substrate; and forming a silicon nitride layer on the DLC film.

### BRIEF DESCRIPTION OF THE DRAWINGS

FIG. 1 illustrates an exemplary DLC structure or stack that includes an oxide overlayer and an intermediate buffer layer formed on a DLC film on a metal substrate.

FIG. 2 is a flow chart summarizing an exemplary method or procedure for forming the stack of FIG. 1.

FIG. 3 illustrates further details of an exemplary DLC structure or stack that includes an oxide overlayer and a buffer layer formed on an ultrathin DLC film on a Ni—Fe substrate.

FIG. 4 illustrates details of an exemplary method or procedure for forming the stack of FIG. 3.

FIG. 5 illustrates an exemplary DLC structure or stack that includes a silicon nitride overlayer formed on a DLC film on a metal substrate with no separate buffer layer.

FIG. 6 is a flow chart summarizing an exemplary method or procedure for forming the stack of FIG. 5.

FIG. 7 illustrates details of an exemplary method or procedure for forming the stack of FIG. 6.

FIG. 8 illustrates an exemplary a disk drive having a slider on which a DLC film stack may be deposited, such as one of the DLC film stacks of FIGS. 1-7.

FIG. 9 illustrates an exemplary assembly of components for use within a disk drive that includes a slider on which a DLC film stack may be deposited, such as one of the DLC film stacks of FIGS. 1-7.

FIG. 10 illustrates another exemplary DLC structure.

FIG. 11 is a flow chart summarizing an exemplary method or procedure for forming the structure of FIG. 10.

FIG. 12 illustrates further details of an exemplary DLC structure.

FIG. 13 illustrates further details of an exemplary method or procedure for forming the structure of FIG. 12.

FIG. 14 illustrates yet another exemplary DLC structure.

FIG. 15 is a flow chart summarizing an exemplary method or procedure for forming the structure of FIG. 16.

FIG. 16 illustrates further details of the exemplary DLC structure of FIG. 14.

FIG. 17 illustrates further details of an exemplary method or procedure for forming the structure of FIG. 16.

### DETAILED DESCRIPTION

In the following detailed description, reference is made to the accompanying drawings, which form a part thereof. In addition to the illustrative aspects, embodiments, and features described above, further aspects, embodiments, and features will become apparent by reference to the drawings and the following detailed description. The description of elements in each figure may refer to elements of proceeding figures. Like numbers may refer to like elements in the figures, including alternate embodiments of like elements.

Aspects described herein are directed to DLC film-based structures, methods for forming such structures, and apparatus using such structures, such a hard disk drives (HDD) or other disk drives having sliders equipped for heat assisted magnetic recording (HAMR), which may also be referred to as energy assisted magnetic recording (EAMR). Within such devices, a protective DLC film (often called a DLC overcoat) may be formed on the portion of the slider that emits the heat and light used for recording data on a hard disk media via the HAMR process. The hard DLC film protects the slider from wear. It may be advantageous in such devices for the DLC film to be ultrathin, with a thickness, for example, of no more than 3.0 nanometers (nm). The ultrathin DLC film permits the HAMR components of the slider to be positioned in very close proximity to the media on which the data is recorded, which facilitates effective and reliable recording. An ultrathin DLC is also substantially transparent at the wavelengths of light used with HAMR (e.g. wavelengths in the range of 800 nm-860 nm), which also facilitates HAMR. The DLC should not be too thin, otherwise it may not provide sufficient protection to the slider and it may lack thermal stability. Hence, a minimum thickness of, for example, 2.0 nm may be used for the DLC film.

Issues may arise when using an ultrathin DLC film of no more than 3.0 nm. For example, the substrate on which the DLC film is formed may be composed of metal, which can oxidize, particularly at the high temperatures associated with HAMR. That is, the thermal oxidation rate of the metal substrate may be too high. This is referred to herein as temperature-based oxidation since the oxidation may be triggered by or otherwise caused by high temperatures. For HAMR, for example, the temperature may exceed 400° C. Moreover, the ultrathin DLC film may lack sufficient thermal stability. By thermal stability, it is meant herein that the DLC film can withstand the high temperatures of HAMR without degradation, particularly graphitization, which is a process by which the DLC film weakens and becomes softer and may become susceptible to fissures or the like. This is referred to herein as a temperature-based loss of thermal stability since the degradation in thermal stability oxidation may be triggered by or otherwise caused by high temperatures. The degradation of the DLC film may result in a loss of optical transparency of the DLC film. This is referred to herein as a temperature-based loss of transparency since the loss of transparency may be triggered by or otherwise caused by high temperatures.

One technique that attempts to address these issues is to dope the DLC film with elements such as Ti, W, Co, Cr, Al, N, or Si. However, doping can result in a DLC film that has greater optical absorption at the wavelengths of HAMR, thus yielding a DLC film that is less transparent at those wavelengths, hence reducing the efficacy and reliability of HAMR. Another possible technique is to employ a higher deposition energy than usual when forming the ultrathin DLC film by using, e.g., ion assisted deposition or laser ablation. However, high deposition energies may result in substrate damage while achieving relatively little improvement in the thermal stability of the DLC film. Yet another technique for attempting to address these issues is to treat the ultrathin DLC film after it has been deposited using hot isostatic pressing. Such post-deposition treatment may, however, achieve minimal improvement in thermal stability of the ultrathin DLC film.

Herein structures, methods and apparatus are disclosed wherein, in some examples, an oxide overlayer is employed above the ultrathin DLC film to reduce oxidation of the substrate while still maintaining optical transparency and thermal stability of the DLC film. A buffer layer formed of, for example, silicon nitride (Si₃N₄), is employed between the DLC film and the oxide overlayer to, e.g., provide a barrier between the oxide overlayer and the DLC film. The buffer layer helps prevent chemical mixing and/or other interactions between the oxide overlayer and the DLC film that might adversely affect the DLC film and reduce the optical transparency or thermal stability of the DLC film. The oxide overlayer may be, for example, hafnium dioxide (HfO₂) or tantalum pentoxide (Ta₂O₅) but other oxides may be used in some examples, as discussed below. The buffer layer may be, as noted, silicon nitride but other buffer materials may be used in some examples, as discussed below. The combined structure of DLC film, the buffer layer, and the overlayer may be referred to as a stack or a film stack.

In other examples described herein, an overlayer formed of silicon nitride is formed directly on the ultrathin DLC film. That is, rather than providing an oxide overlayer and a separate silicon nitride buffer layer, the silicon nitride is employed as the overlayer (with no separate buffer layer). The use of silicon nitride on the ultrathin DLC film also serves to reduce oxidation of the substrate while maintaining optical transparency and thermal stability of the DLC film.

Exemplary Structures with Ultrathin DLC Film, Buffer Layer, and Oxide Overlayer

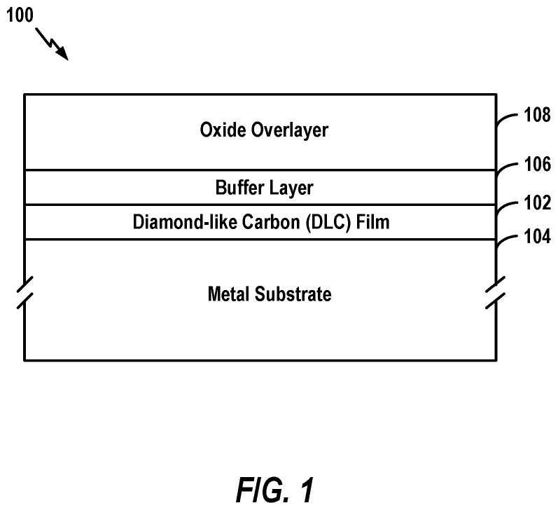

FIG. 1 illustrates an exemplary DLC film structure or stack 100 that includes a DLC film 102 formed on a metal substrate 104. A buffer layer 106 is formed on the DLC film 102. An oxide overlayer 108 is formed on the buffer layer. Although terms such as film, layer, buffer, and substrate are shown in FIG. 1, it should be understood that other terms may be used, where appropriate, such as coating, barrier, deposit, base, stratum, etc. And so the metal substrate 104 may be, for example, a metal base or metal stratum. The DLC film may be DLC coating, layer or sheet. The buffer layer 106 may be a barrier, a shield, or a guard layer. The overlayer may be a coating, layer, sheet, covering or capping layer. These are just some exemplary terms.

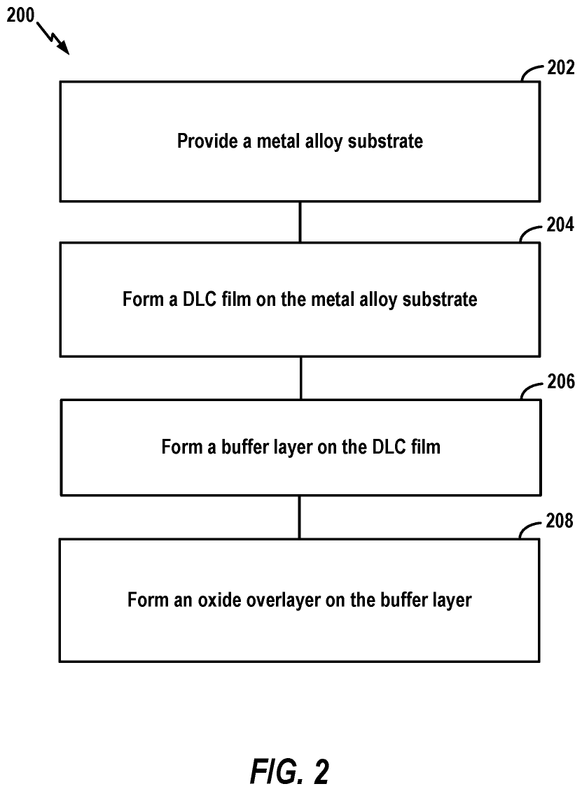

FIG. 2 summarizes an exemplary method or procedure 200 for forming the structure or stack of FIG. 1. Briefly, at block 202, a metal substrate is provided, such as the bottom surface of a slider of a HAMR HDD. At block 204, a deposition or fabrication apparatus, such as a vacuum deposition apparatus, forms a DLC film on the substrate, such as an ultrathin DLC film. At block 206, the deposition or fabrication apparatus forms a buffer layer on the DLC film, such as a silicon nitride buffer layer. At block 208, the deposition or fabrication apparatus forms an oxide overlayer on the buffer layer. The next several figures illustrate exemplary compounds and materials.

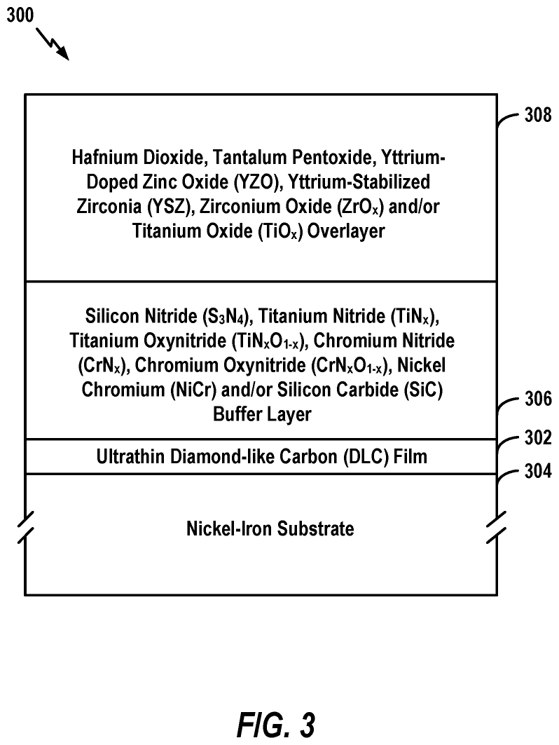

FIG. 3 illustrates an exemplary DLC film structure or stack 300 that includes an ultrathin DLC film 302 formed directly on a nickel-iron metal alloy substrate 304. Nickel-iron is often used in HAMR sliders and other HDD sliders but nickel-iron is just one example of a substrate material. The DLC film 302 may have a thickness, for example, of no more than 3.0 nm and may be, for example, in the range of 2.0 nm to 3.0 nm. A buffer layer 306 is formed directly on the DLC film 304 where the buffer layer includes one or more of silicon nitride (S₃N₄), titanium nitride (TiNₓ), titanium oxynitride (TiNₓO_{y}), chromium nitride (CrNₓ), chromium oxynitride (CrNₓO_{y}), nickel chromium (NiCr) and/or silicon carbide (SiC) buffer layer. Within illustrative examples, TiNₓO₁₋ₓ films where x is in the range of 0.5 to 1 are used (where x refers to fraction of N in N+O atoms participating in the formation of Ti—N—O compound). (Titanium Nitride is sometimes referred to as Tinite.) Within illustrative examples, CrNₓO₁₋ₓ films where x is in the range of 0.5 to 1 are used. An oxide overlayer 308 is formed over the buffer layer 306 where the oxide overlayer includes one or more of hafnium dioxide, tantalum pentoxide, yttrium-doped zinc oxide (YZO), yttrium-stabilized zirconia (YSZ), zirconium oxide (ZrOₓ) and/or titanium oxide (TiOₓ). Within illustrative examples, ZrOₓ films where x is in the range of 0.5 to 2 are used. Within illustrative examples, TiOₓ films where x is in the range of 0.5 to 2 are used. When using silicon nitride, the buffer layer 306 may have a thickness of, for example, at least 0.5 nm and may be, for example, in the range of 0.5 to 1.0 nm.

Other buffer materials instead of those listed in FIG. 3 may be used as well, with the particular buffer material selected from compounds or materials capable of providing a sufficient barrier to chemical mixing/interaction between oxide overlayer and DLC film. In this regard, otherwise routine experimentation may be performed to identify suitable buffer compounds that achieve some desired or acceptable degree of prevention of chemical mixing/interaction as compared, for example, to a threshold indicative of a maximum acceptable amount of chemical mixing/interaction. Such mixing/interaction may result in degradation of the DLC film, which in turn, may be reflected in a loss of optical transparency. Hence, an acceptable degree of prevention of chemical mixing/interaction may be quantified in terms of a loss of optical transparency to the underlying DLC film. Insofar as optical transparency is concerned, optical transparency of the DLC film may be quantified in terms of surface plasmon propagation (Gspp). For example, a maximum acceptable loss of optical transparency may be quantified as a maximum acceptable reduction in Gspp. The amount of chemical mixing/interaction may depend on the thickness of the various layers of the overall structure and on other factors such as operational temperatures.

Likewise, other overlayer oxide materials instead of those listed in FIG. 3 may be used as well, with the particular overlayer material selected from compounds or materials capable of providing thermal stability to the DLC film and high optical transparency to the DLC film (within, e.g., the 800 nm-860 nm wavelengths used in HAMR). In this regard, otherwise routine experimentation may be performed to identify suitable overlayer compounds that achieve some desired or acceptable degree of thermal stability and optical transparency in the DLC film as compared, for example, to thresholds indicative of minimum acceptable levels of thermal stability and optical transparency (or, conversely, a maximum acceptable amount of loss of thermal stability or optical transparency). As noted, optical transparency may be quantified in terms of Gspp. The degree of thermal stability and optical transparency again may depend on the thickness of the various layers of the overall structure and on other factors such as operational temperatures.

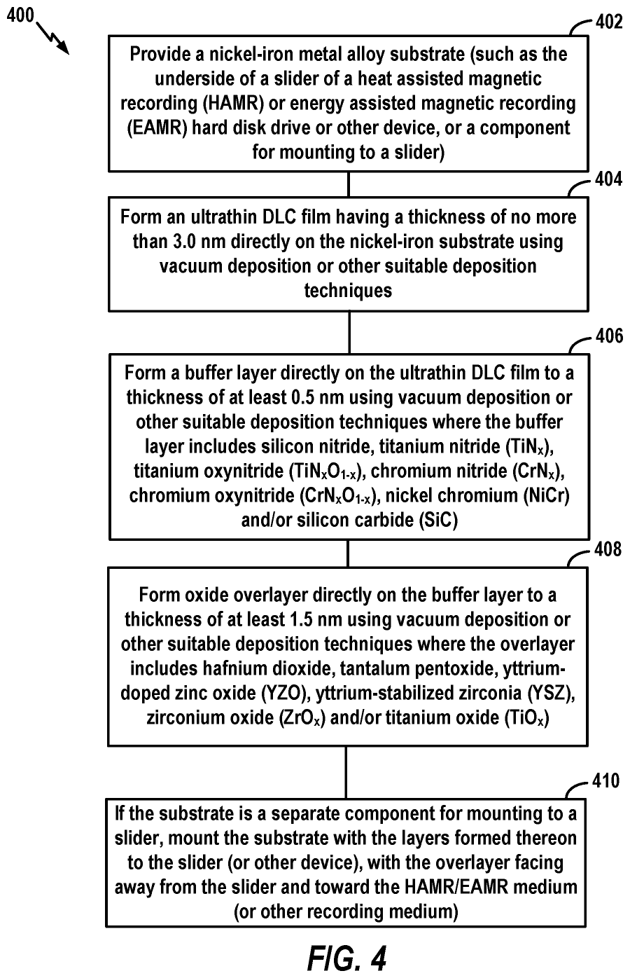

FIG. 4 illustrates an exemplary method or procedure 400 for forming the structure or stack of FIG. 3. At block 402, a nickel-iron metal alloy substrate is provided as (at least a portion of) the underside of a slider of a HAMR or EAMR hard disk drive or other device (or, in some examples, the substrate is a component configured for mounting to the underside of the slider). At block 404, a deposition or fabrication apparatus, such as a vacuum deposition apparatus, forms an ultrathin DLC film directly on the substrate having a DLC film thickness no more than 3.0 nm. (In examples where the substrate is the underside of the slider, the DLC film is thus deposited directly onto at least a portion of the underside of the slider or the entire underside of the slider. In other examples, the DLC film may be deposited, additionally or alternatively, on other sides of the slider, such as on its top surface or side surfaces, or over the entire slider. Moreover, it should be understood that such terms as underside, top surface, or side surface are, at least in some cases, arbitrary terms and so what may be called the underside in on example might be called a top side in another example.) At block 406, the deposition or fabrication apparatus forms a buffer layer directly on the ultrathin DLC film with a buffer layer thickness of 0.5 nm, where the buffer layer includes one or more of S₃N₄, TiNₓO₁₋ₓ, CrNₓO₁₋ₓ, NiCr and/or silicon carbide SiC buffer layer, or other suitable buffer materials. At block 408, the deposition or fabrication apparatus forms an oxide overlayer directly on the nitride buffer layer with an oxide overlayer a thickness of at least 1.5 nm, where the oxide overlayer includes hafnium dioxide, tantalum pentoxide, YZO, YSZ, ZrOₓ and/or TiOₓ or other suitable capping materials. At 410, if the substrate is a separate component for mounting to the slider, the substrate with the layers formed thereon is then mounted to the slider or other device, with the overlayer facing away from the slider and toward a HAMR/EAMR medium (or other recording medium). As noted above, the substrate may be a portion of the underside of the slider and, if so, the substrate need not be mounted to the slider. Otherwise routine experimentation may be performed to determine preferred thicknesses for the various layers, which may depend, for example, on the operational details of the particular HAMR/EAMR drive, such as the wavelength of the HAMR/EAMR laser and the temperatures to be achieved during operation.

Note that all oxides and nitrides mentioned herein can be formed with conventional vacuum deposition processes to produce desired or selected film stoichiometry without a significant temperature increase as compared to procedures used to form DLC films without oxide and nitride layers so as to avoid damaging the DLC film (e.g. the increase is less than 100° C.).

At least some potential advantages of the structures of FIGS. 1-4 include 1) improving oxidation resistance of underlying metal structure and 2) maintaining the surface plasmon propagation (Gspp) loss (i.e. film optical transparency). Note that the DLC film protects the underlying metal (often a NiFe alloy) against thermal oxidation and the environment. Bare NiFe alloy oxidizes at 300° C. NiFe alloy with a 2-3 nm DLC film deposited on its surface oxidizes instead at 400° C. (which is the temperature at which many HAMR/EAMR drives operate). The metal (Fe) oxidation temperature is limited as such because DLC film starts to lose its integrity at elevated temperatures and can no longer protect the metal. A 2-3 nm DLC film may, for example, lose 50% of its mass when heated to 550° C. The underlying metal oxidizes at higher temperatures when the DLC film thermal stability improves. When Ta₂O₅, HfO₂, or Si₃N₄ are deposited onto DLC film, the temperature that DLC loses 50% of its mass may increase from 550° C. to 600° C., 625° C., and 725° C., respectively. Correspondingly, Fe-oxidation temperature may increase from 400° C. to 450° C., 550° C., and 650° C. for DLC film with Ta₂O₅, HfO₂, or Si₃N₄ overlayer materials, respectively. This may enable devices to operate more reliably at elevated temperature.

Table I provides exemplary values for C-mass loss temperature, Fe-oxidation temperature, and surface plasmon propagation (Gspp) loss for exemplary structures or stacks. The values for C-mass loss and Fe-oxidation were measured with Raman spectroscopy under non-isothermal heating condition. The values for Gssp were measured with Attenuated Total Reflectance technique under Kretschmann configuration to extract surface plasmon propagation value (dB/μm).

TABLE I

| Overlayer | | Buffer | DLC | | C-mass loss | Fe-oxidation | Gspp |
|---|---|---|---|---|---|---|---|
| Material/thickness | | Material/thickness | thickness | | (C) | (C) | (dB/um) |
| — | | — | — | | — | 300 | — |
| — | | — | 2-3 | nm | 550 | 400 | 0.38-0.39 |
| Ta₂O₅/2 | nm | Si₃N₄/0.5 nm | 2 | nm | 600 (est.) | 450 | 0.30 |
| HfO₂/2 | nm | Si₃N₄/0.5 nm | 2 | nm | 625 | 550 | 0.32 |
| Si₃N₄/2 | nm | — | 2 | nm | 700 | 650 | 0.2 |

Note that depositing the oxides or nitrides on the DLC film does not significantly change the overall film surface Gspp loss property, which quantifies the propensity for light to be absorbed by the film. In this regard, a 2-3 nm DLC film with the described oxide or nitride layers and a 2-3 nm DLC film without those layers were found to have a substantially equivalent Gspp of ˜0.40 dB/um, which suggests no optical performance difference. The stacks described herein are thus suitable for use as protective films for devices that require high thermal stability and high optical transparency, such as HAMR devices or other energy-assisted recording heads. Note that a (Hysitron) nano-wear test shows 5-fold increase in wear depth of the HfO₂ overlayered structure as compared to regular non-overlayered DLC film. This may be expected as oxide film is known to be less mechanically robust than a DLC film. However, this compromise can be mitigated by optimizing or compensating based on device topography. Optimum topography can reduce overall head-disk interactions and improve its wear margin. Thus, the benefits of enhanced film thermal stability afforded by the oxide overlayer can be gained without significant adverse characteristics.

Exemplary Structures with Ultrathin DLC Film and Silicon Nitride Overlayer

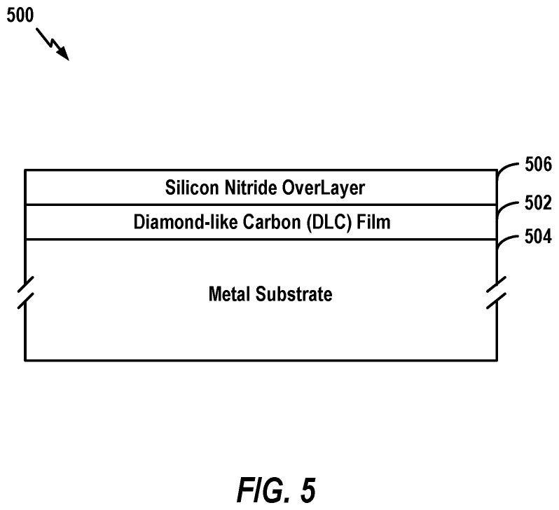

FIG. 5 illustrates an exemplary DLC film structure or stack 500 that includes a DLC film 502 formed on a metal substrate 504. A silicon nitride overlayer 506 is formed on the DLC film 502.

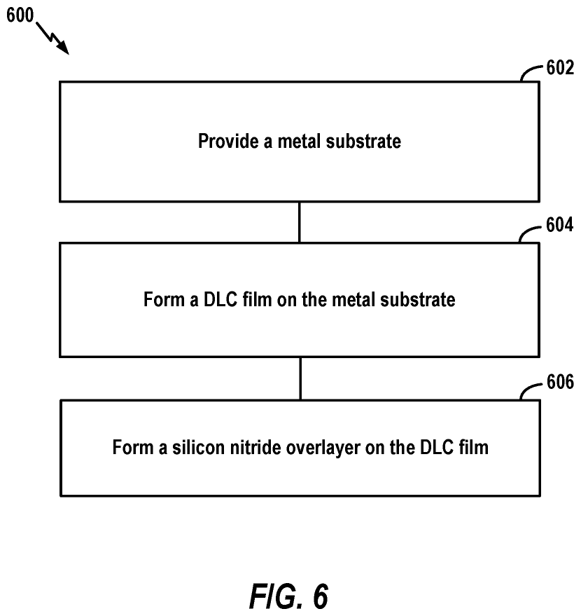

FIG. 6 summarizes an exemplary method or procedure 600 for forming the structure of FIG. 5. Briefly, at block 602, a metal substrate is provided, such as the bottom surface of a slider of a HAMR HDD. At block 604, a deposition or fabrication apparatus, such as a vacuum deposition apparatus, forms a DLC film on the substrate, such as an ultrathin DLC film. At block 606, the deposition or fabrication apparatus forms a silicon nitride overlayer directly on the DLC film.

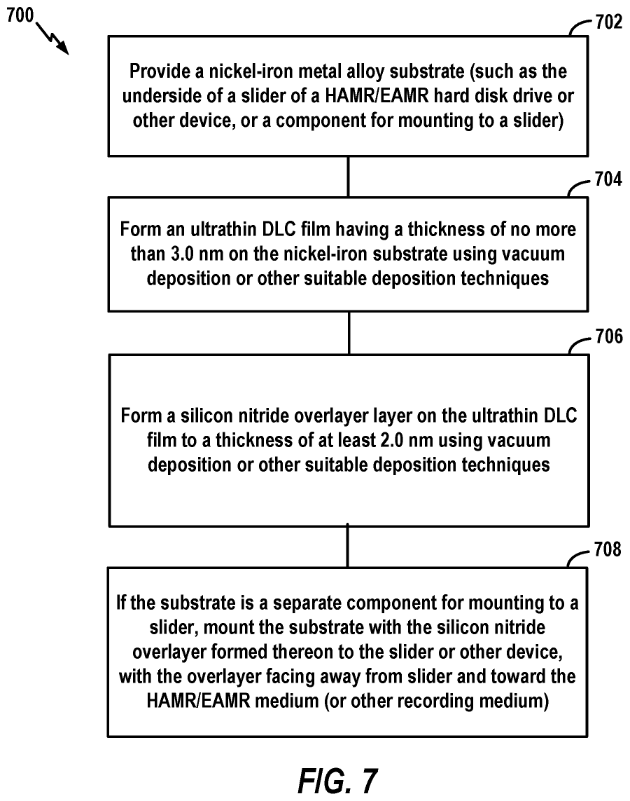

FIG. 7 illustrates further details of an exemplary method or procedure 700 for forming the structure of FIG. 5. At block 702, a nickel-iron metal alloy substrate is provided as the underside of the slider of a HAMR or EAMR hard disk drive or other device (or, in some examples, the substrate is configured for mounting to the underside of the slider). At block 704, a deposition or fabrication apparatus, such as a vacuum deposition apparatus, forms an ultrathin DLC film on the substrate having a thickness no more than 3.0 nm and, for example, in the range of 2.0 to 3.0 nm. (In examples where the substrate is the underside of the slider, the DLC film is thus deposited directly onto the underside of the slider.) At block 706, the deposition or fabrication apparatus forms a silicon nitride overlayer directly on the ultrathin DLC film to a thickness of at least 2.0 nm and, for example, in the range of 2.0 nm to 2.5 nm. At 708, if the substrate is a separate component for mounting to the slider, the substrate with the silicon nitride overlayer formed thereon is mounted to the slider or other device, with the overlayer facing away from the slider and toward the HAMR/EAMR medium (or other recording medium). As noted, the substrate may be a portion of the underside of the slider and, if so, the substrate need not be mounted to the slider. Otherwise routine experimentation may be performed to determine preferred thicknesses for the layers, which may depend, for example, on the operational details of the particular HAMR/EAMR drive, such as the wavelength of the HAMR/EAMR laser and the operational temperatures to be achieved.

Exemplary Slider for Storage Device with Ultrathin DLC Coating and Buffer/Overlayers

The above-described structures employing coated ultrathin DLC films may be formed onto components or devices of an HDD and, for the sake of completeness, a brief description will now be provided of an exemplary HDD that has a slider where at least one surface portion of the slider is coated with a DLC film stack that includes either a silicon nitride overlayer formed directly on the DLC film or an oxide overlayer formed over an intervening buffer layer. The particular example of an HDD configured for HAMR/EAMR, but the DLC film structures described herein may be used in other HDD designs with other recording technologies and a slider is just one component of an HDD component that may have a DLC film coating. Hence, the following is merely illustrative and not limiting.

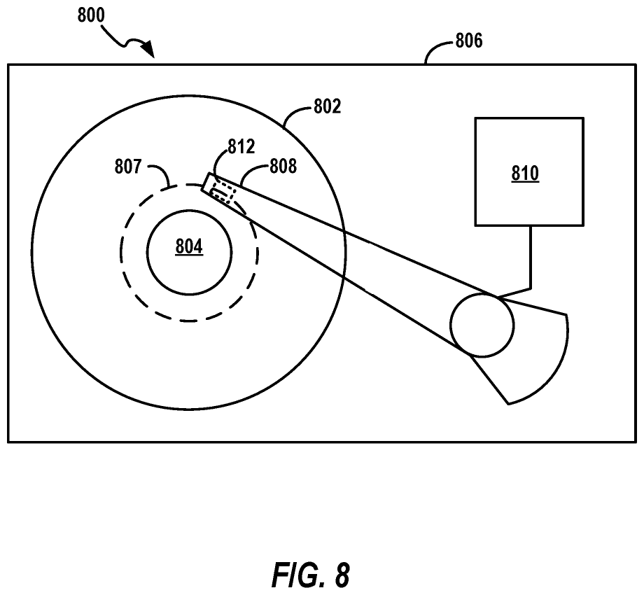

FIG. 8 illustrates a disk drive 800 configured for HAMR/EAMR. The disk drive 800 includes one or more media 802, a spindle assembly 804, a drive housing 806, a slider 808 and control circuitry 810. The slider 808 may include a slider head 812 (shown in dashed lines as it is formed on the underside of the distal end of the slider 808. The slider 808 may be used to position a laser (not shown in FIG. 8). The one or more media 802 may be configured to store data. The media 802 may be a magnetic recording medium, such as a HAMR medium, in the form of a disk, or any other suitable means for storing data. The media 802 is positioned on the spindle assembly 804 that is mounted to the drive housing 806. Data may be stored along tracks in the magnetic recording layer of the media 802. The reading and writing of data are accomplished with a read element and a write element located with the slider 808. The write element is used to alter the properties of the magnetic recording layer of the media 802 and thereby write information thereto. In some implementations, the slider 808 may include an inductive read/write head or a Hall Effect head. During operation of the disk drive 800, a spindle motor (not shown) rotates the spindle assembly 804, and thereby rotates the media 802. The slider 808 and the laser (not shown) may be positioned over the media 802 at a particular location along a desired disk track, such as track 807 shown in dashed lines. The positions of the slider 808 and the laser relative to the media 802 may be controlled by the control circuitry 810.

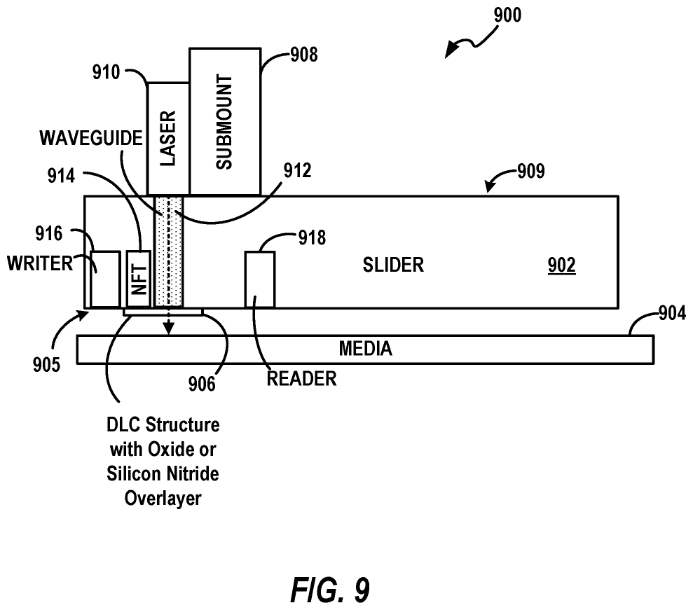

FIG. 9 illustrates a side view of an exemplary assembly 900 that includes a slider 902 and a HAMR or EAMR medium 904 where a bottom surface 905 of the slider 902 includes a DLC structure 906 of the type described above that includes either a silicon nitride overlayer formed directly on a DLC film or an oxide overlayer formed over an intervening buffer layer that is formed on the DLC film. In some examples, the DLC film of the DLC structure 906 is formed directly on the bottom surface or underside 905 of the slider 902 (where the underside 905 is the above-described metal alloy substrate). In other examples, the DLC film is formed on a separate substrate that is mounted to or otherwise attached or affixed to the underside 905 of the slider. In the example of FIG. 9, the DLC structure coating 906 extends over only one exemplary portion of the bottom surface 905 of the slider 902 but, additionally or alternatively, other portions of the slider (or other components of assembly 900) may have DLC stacks as well. The DLC coating 906 is not shown to scale.

The assembly 900 also includes a sub-mount 908, a laser 910, a waveguide 912, a near-field transducer (NFT) 914, a writer 916 and a reader 918. The assembly 900 is positioned over the HAMR media 904. The slider 902 may be one component or several components. For example, the slider 902 may include a slider and a slider head (not separately shown). In some implementations, the slider head may be a separate component mounted to the slider 902. In some examples, the DLC structure 906 may be formed on or mounted on the slider head. (As noted above, the DLC film may be formed directly on the underside of the slider, and so the underside of the slider is the “substrate” layer of the DLC structure. In other examples, the substrate of the DLC structure may be a separate component mounted to the underside of the slider with the DLC film formed on that separate substrate.) The sub-mount 908, the laser 910, the waveguide 912, the NFT 914, the writer 916 and the reader 918 may be implemented in the slider, the slider head or combinations thereof.

The bottom (first) surface 905 of the slider 902 faces the media 904. The bottom surface 905 may be referred to as an air bearing surface (ABS). The slider 902 also includes a top (second) surface 909 that faces away from the media 904. The sub-mount 908 is coupled to the top surface 909. The laser 910 is coupled to the sub-mount 908, and in some examples, to the slider 902. The waveguide 912, the NFT 914, the writer 916 and the reader 918 may be located near or along the ABS 905 of the slider 902. The writer 916 may be configured as a writing element or means for writing data on the media 904, and the reader 918 may be configured as a reading element or means for reading data on the media 904.

The laser 910 is configured to generate and transmit light energy (e.g., a laser beam) into the waveguide 912, which directs light energy to and/or near the NFT 914, which is near the ABS 905 of the slider 902. Upon receiving and/or being near the light energy, the NFT 914 may cause a portion of the media 904 to heat up, and/or the light energy traveling through the waveguide may heat a portion of the media 904. For example, upon receiving and/or being near the light energy, the NFT 914 may generate localized heat that heats a portion of the media. Thus, the light energy may travel through the waveguide 912 such that the NFT 914 emits heat to a portion of the media 904. In the example of FIG. 9, the DLC structure 906 is positioned so at least a portion of the heat and/or light energy passes through the DLC structure 906, which is configured, as discussed above, to be sufficiently thin to permit the portion of heat and/or light energy to pass through it. That is, the DLC structure is sufficiently optically transparent at the operational wavelengths of the laser 910 (e.g. in the range of 800 nm-860 nm) to permit the portion of heat and/or light energy to pass through the DLC structure to record data on the media 904. As already explained, the overlayers of the DLC structures of FIGS. 1-7 serve to reduce oxidation of the DLC film without unduly reducing its optical transparency and its thermal stability. In other examples, the DLC structure may be positioned elsewhere on the bottom (ABS) surface 905 of the slider 902.

### Additional Exemplary Structures and Methods

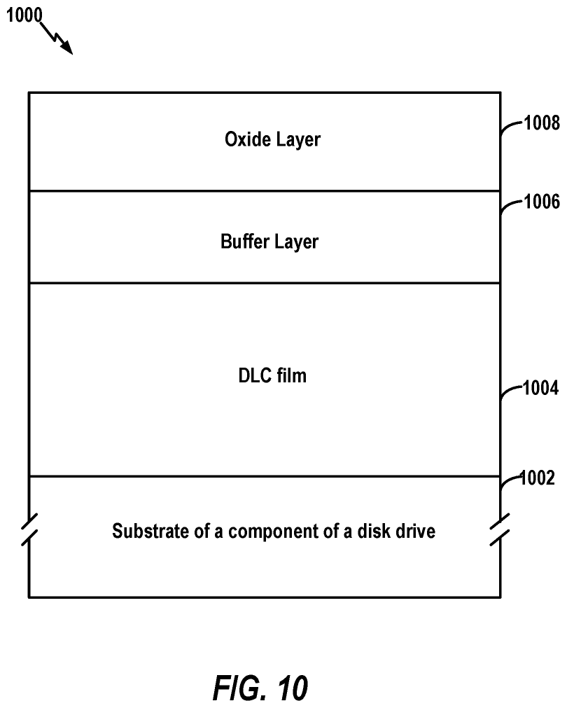

FIG. 10 illustrates an exemplary structure 1000 for use in a disk drive, where the structure includes a DLC film 1002 formed over a substrate 1004 of a component of the disk drive. A buffer layer 1006 is formed over the DLC film 1002. An oxide layer 1008 is formed over the buffer layer. As discussed above, the component of the disk drive may be, for example, a slider. The substrate may be, in some examples, a portion of the slider, such as its underside, or a portion of the underside of the slider, such as the portion at or near one end of a waveguide of a HAMR/EAMR slider. In other examples, the component may be a substrate that is mounted to a device within the disk drive, where the device may be, e.g., a slider.

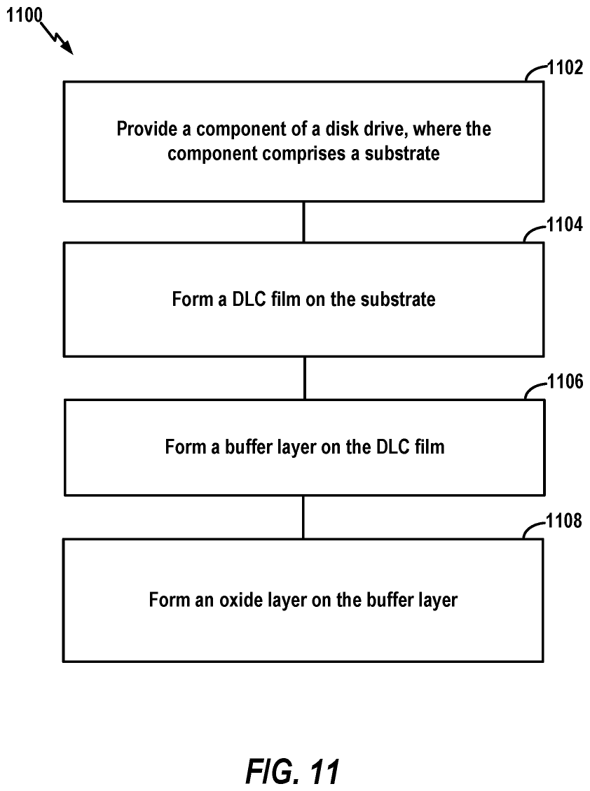

FIG. 11 summarizes an exemplary method or procedure 1100 for forming the structure of FIG. 10. Briefly, at block 1102, a component of a disk drive is provided, where the component comprises or includes a substrate. At block 1104, a deposition or fabrication apparatus forms a DLC film on the substrate. At block 1106, the deposition or fabrication apparatus forms a buffer layer on the DLC film. At block 1108, the deposition or fabrication apparatus forms an oxide layer on the buffer layer. Again, the component of the disk drive may be, for example, a slider. The substrate may be, in some examples, a portion of the slider, such as its underside, or a portion of the underside of the slider, such as the portion at or near one end of a waveguide of a HAMR/EAMR slider. In other examples, the component may be a substrate that is mounted to a device within the disk drive, where the device may be, e.g., a slider.

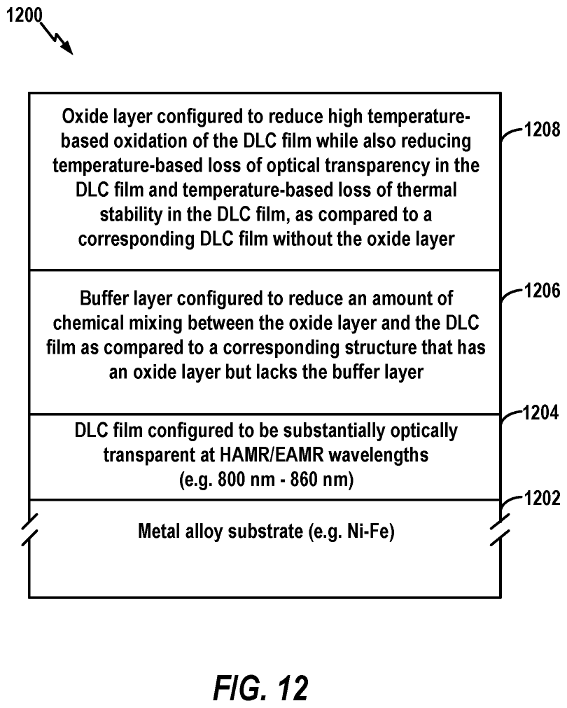

FIG. 12 illustrates an exemplary DLC film structure 1200 that includes a DLC film 1202 formed directly on a metal alloy substrate 1204 (such as a Ni—Fe substrate). The DLC film 1202 is configured to be substantially optically transparent at HAMR/EAMR wavelengths (e.g. 800 nm-860 nm). The DLC film may be so configured by, e.g., configuring or selecting its thickness to be no more than 3.0 nm or, for example, in the range of 2.0 nm to 3.0 nm. A buffer layer 1206 is formed directly on the DLC film. The buffer layer is configured to reduce an amount of chemical mixing between an oxide layer and the DLC film as compared to a corresponding structure that has an oxide layer but lacks the buffer layer. The buffer layer 1206 may be so configured by, for example, configuring or selecting its thickness to be least 0.5 nm or, for example, in the range of 0.5 to 1.0 nm, and further by selecting the choice of compound for use as the buffer material. For example, the buffer layer may be configured to reduce an amount of chemical mixing by depositing a compound selected from a group including S₃N₄, TiNₓO₁₋ₓ, CrNₓO₁₋ₓ, NiCr and/or SiC. When using TiNₓO₁₋ₓ or CrNₓO₁₋ₓ, the buffer layer may be configured by selecting a particular choice of x.

An oxide layer 1208 is formed over the buffer layer 104 where the oxide layer is configured to reduce high temperature-based oxidation of the DLC film while also reducing temperature-based loss of optical transparency in the DLC film and temperature-based loss of thermal stability in the DLC film, as compared to a corresponding DLC film without the oxide layer. The oxide layer 1208 may be so configured by, for example, configuring or selecting its thickness to be least 1.5 nm or, for example, in the range of 1.5 to 2.0 nm, and further by selecting the choice of compound for use as the oxide material. For example, the oxide layer may be configured to achieve one or more of the above-mentioned goals by depositing an oxide compound selected from a group including hafnium dioxide, tantalum pentoxide, YZO, YSZ, ZrOₓ and TiOₓ. When using TiOₓ or ZrOₓ, the oxide layer may be configured by selecting a particular choice of x.

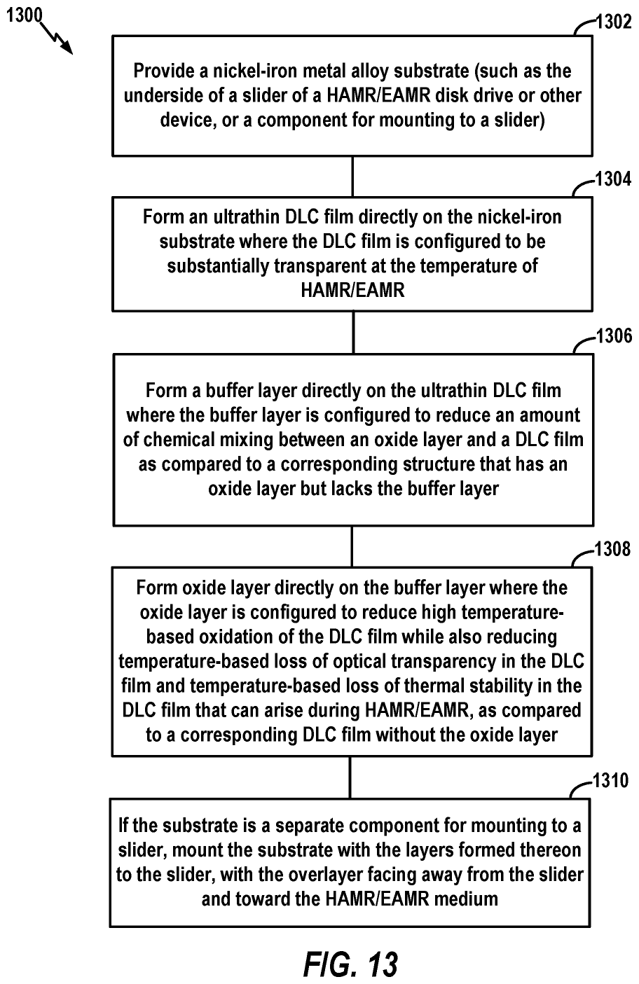

FIG. 13 illustrates an exemplary method or procedure 1300 for forming the structure of FIG. 12 of other suitable structures. At 1302, a nickel-iron metal alloy substrate is provided as (at least a portion of) the underside of the slider of a HAMR/EAMR disk drive or other device or a component for mounting to a slider of other device). At 1304, an ultrathin DLC film is formed directly on the nickel-iron substrate where the DLC film is configured to be substantially transparent at the temperature of HAMR/EAMR. At 1306, a buffer layer is formed directly on the ultrathin DLC film where the buffer layer is configured to reduce an amount of chemical mixing between an oxide layer and a DLC film as compared to a corresponding structure that has an oxide layer but lacks the buffer layer. At 1308, an oxide layer is formed directly on the buffer layer where the oxide layer is configured to reduce high temperature-based oxidation of the DLC film while also reducing temperature-based loss of optical transparency in the DLC film and temperature-based loss of thermal stability in the DLC film that can arise during HAMR/EAMR, as compared to a corresponding DLC film without the oxide layer. At 1310, if the substrate is a separate component for mounting to a slider, mount the substrate with the layers formed thereon to the slider, with the overlayer facing away from the slider and toward the HAMR/EAMR medium. As noted, the substrate may be a portion of the underside of the slider and, if so, the substrate need not be mounted to the slider.

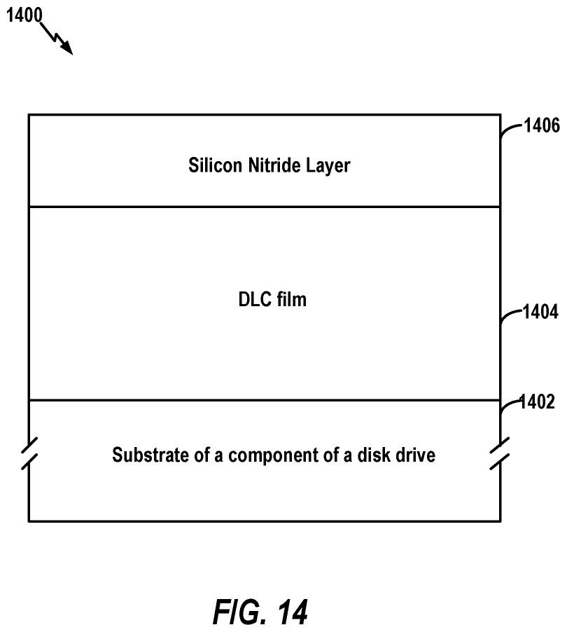

FIG. 14 illustrates an exemplary DLC film structure 1400 that includes a DLC film 1402 formed over a substrate 1404 of a component of a disk drive. A silicon nitride layer 506 is formed over the DLC film 502. Again, the component of the disk drive may be, for example, a slider. The substrate may be, in some examples, a portion of the slider, such as its underside, or a portion of the underside of the slider, such as the portion at or near one end of a waveguide of a HAMR/EAMR slider. In other examples, the component may be a substrate that is mounted to a device within the disk drive, where the device may be, e.g., a slider.

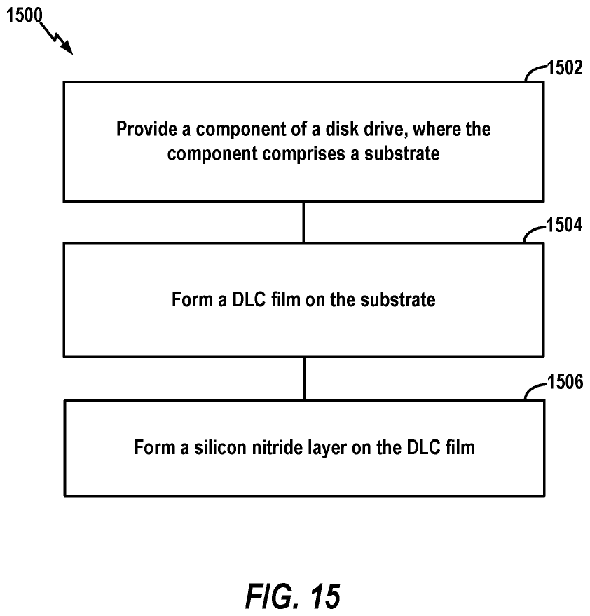

FIG. 15 summarizes an exemplary method or procedure 1500 for forming the structure of FIG. 14. Briefly, at block 1502, a component of a disk drive is provided, where the component includes or comprises a substrate. At block 1504, a deposition or fabrication apparatus forms a DLC film on the substrate. At block 1506, the deposition or fabrication apparatus forms a silicon nitride layer on the DLC film. Again, the component of the disk drive may be, e.g., a slider. The substrate may be, in some examples, a portion of the slider, such as its underside, or a portion of the underside of the slider, such as the portion at or near one end of a waveguide of a HAMR/EAMR slider. In other examples, the component may be a substrate that is mounted to a device within the disk drive, where the device may be, e.g., a slider.

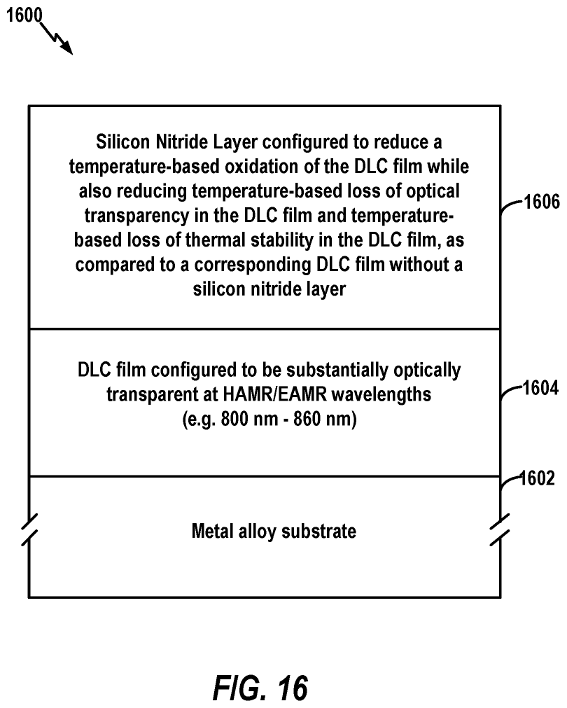

FIG. 16 illustrates an exemplary DLC film structure 1600 that includes a DLC film 1602 formed directly on a metal alloy substrate 1604 (such as a nickel-iron substrate). The DLC film 1602 is configured to be substantially optically transparent at HAMR/EAMR wavelengths (e.g. 800 nm-860 nm). The DLC film may be so configured by, as already explained, configuring or selecting its thickness to be no more than 3.0 nm or, for example, in the range of 2.0 nm to 3.0 nm. A silicon nitride layer 1606 is formed directly on the DLC film. The silicon nitride layer is configured to reduce high temperature-based oxidation of the DLC film while also reducing temperature-based loss of optical transparency in the DLC film and temperature-based loss of thermal stability in the DLC film, as compared to a corresponding DLC film without the silicon nitride layer. The silicon nitride layer 1606 may be so configured by, for example, configuring or selecting its thickness to be least 2.0 nm or, for example, in the range of 2.0 to 2.5 nm.

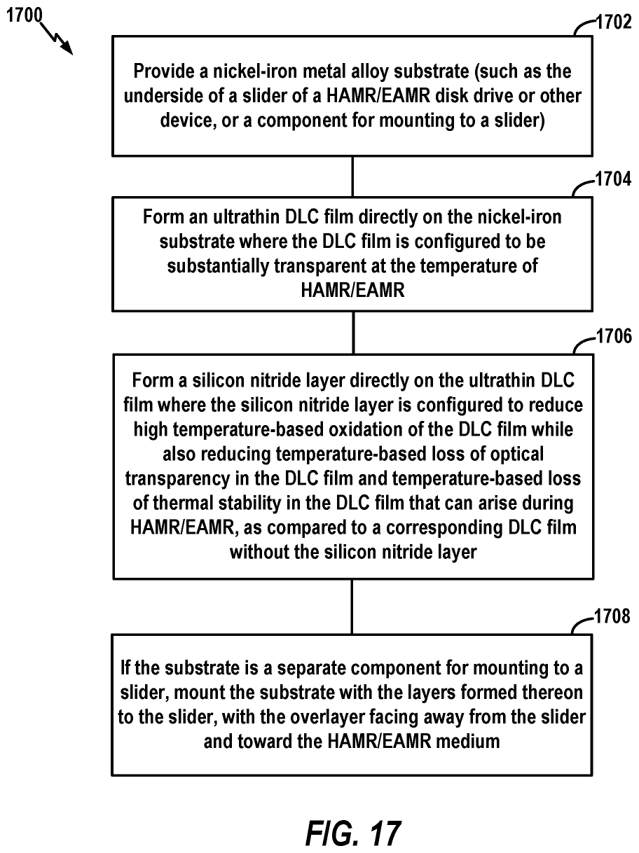

FIG. 17 illustrates further details of an exemplary method or procedure 1700 for forming the structure of FIG. 16. At block 1702, a nickel-iron metal alloy substrate is provided as (at least a portion of) the slider of a HAMR or EAMR disk drive or other device (or, in some examples, the substrate is mounted to the underside of the slider). At block 1704, a deposition or fabrication apparatus, such as a vacuum deposition apparatus, forms an ultrathin DLC film on the substrate having a thickness no more than 3.0 nm and, for example, in the range of 2.0 to 3.0 nm. (In examples where the substrate is the underside of the slider, the DLC film is thus deposited directly onto the underside of the slider.) At block 1706, the deposition or fabrication apparatus forms a silicon nitride layer directly on the ultrathin DLC film where the silicon nitride layer is configured to reduce high temperature-based oxidation of the DLC film while also reducing temperature-based loss of optical transparency in the DLC film and temperature-based loss of thermal stability in the DLC film, as compared to a corresponding DLC film without the silicon nitride layer. The silicon nitride layer may be so configured by, as already explained, configuring or selecting its thickness to be least 1.5 nm or, e.g., in the range of 1.5 to 2.0 nm. At 1708, if the substrate is a separate component for mounting to the slider, the substrate with the silicon nitride layer formed thereon is then mounted to the slider or other device, with the silicon nitride layer facing away from the slider and toward the HAMR/EAMR medium (or other recording medium). As noted, the substrate may be a portion of the underside of the slider and, if so, the substrate need not be mounted to the slider.

The examples set forth herein are provided to illustrate certain concepts of the disclosure. The apparatus, devices, or components illustrated above may be configured to perform one or more of the methods, features, or steps described herein. Those of ordinary skill in the art will comprehend that these are merely illustrative in nature, and other examples may fall within the scope of the disclosure and the appended claims. Based on the teachings herein those skilled in the art should appreciate that an aspect disclosed herein may be implemented independently of any other aspects and that two or more of these aspects may be combined in various ways. For example, an apparatus may be implemented or a method may be practiced using any number of the aspects set forth herein. In addition, such an apparatus may be implemented or such a method may be practiced using other structure, functionality, or structure and functionality in addition to or other than one or more of the aspects set forth herein.

Aspects of the present disclosure have been described above with reference to schematic flowchart diagrams and/or schematic block diagrams of methods, apparatus, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

The subject matter described herein may be formed by an apparatus controlled by hardware, software, firmware, or any combination thereof. As such, the terms “function,” “module,” and the like as used herein may refer to hardware, which may also include software and/or firmware components, for implementing the feature being described. In one example implementation, the subject matter described herein may be implemented using a computer readable or machine readable medium having stored thereon computer executable instructions that when executed by a computer (e.g., a processor) control the computer to perform the functionality described herein. Examples of machine readable media suitable for implementing the subject matter described herein include non-transitory computer-readable media, such as disk memory devices, chip memory devices, programmable logic devices, and application specific integrated circuits. In addition, a machine readable medium that implements the subject matter described herein may be located on a single device or computing platform or may be distributed across multiple devices or computing platforms.

It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated figures. Although various arrow types and line types may be employed in the flowchart and/or block diagrams, they are understood not to limit the scope of the corresponding embodiments. For instance, an arrow may indicate a waiting or monitoring period of unspecified duration between enumerated steps of the depicted embodiment.

The various features and processes described above may be used independently of one another, or may be combined in various ways. All possible combinations and sub-combinations are intended to fall within the scope of this disclosure. In addition, certain method, event, state or process blocks may be omitted in some implementations. The methods and processes described herein are also not limited to any particular sequence, and the blocks or states relating thereto can be performed in other sequences that are appropriate. For example, described tasks or events may be performed in an order other than that specifically disclosed, or multiple may be combined in a single block or state. The example tasks or events may be performed in serial, in parallel, or in some other suitable manner. Tasks or events may be added to or removed from the disclosed example embodiments. The example systems and components described herein may be configured differently than described. For example, elements may be added to, removed from, or rearranged compared to the disclosed example embodiments.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The word “exemplary” is used herein to mean “serving as an example, instance, or illustration.” Any aspect described herein as “exemplary” is not necessarily to be construed as preferred or advantageous over other aspects. Likewise, the term “aspects” does not require that all aspects include the discussed feature, advantage or mode of operation.

While the above descriptions contain many specific embodiments of the invention, these should not be construed as limitations on the scope of the invention, but rather as examples of specific embodiments thereof. Accordingly, the scope of the invention should be determined not by the embodiments illustrated, but by the appended claims and their equivalents. Moreover, reference throughout this specification to “one embodiment,” “an embodiment,” or similar language means that a particular feature, structure, or characteristic described in connection with the embodiment is included in at least one embodiment of the present disclosure. Thus, appearances of the phrases “in one embodiment,” “in an embodiment,” and similar language throughout this specification may, but do not necessarily, all refer to the same embodiment, but mean “one or more but not all embodiments” unless expressly specified otherwise.

Certain components (including layers, coatings, or other components) listed herein may be described as “comprising,” “made of,” “including,” or similar such terms, a material or a combination of materials. In one aspect, each of those components may also consist of that material or the combination of materials. In another aspect, each of those components may also consist essentially of that material or the combination of materials.

The terminology used herein is for the purpose of describing particular aspects only and is not intended to be limiting of the aspects. As used herein, the singular forms “a,” “an” and “the” are intended to include the plural forms as well (i.e., one or more), unless the context clearly indicates otherwise. An enumerated listing of items does not imply that any or all of the items are mutually exclusive and/or mutually inclusive, unless expressly specified otherwise. It will be further understood that the terms “comprises,” “comprising,” “includes” “including,” “having,” an variations thereof when used herein mean “including but not limited to” unless expressly specified otherwise. That is, these terms may specify the presence of stated features, integers, steps, operations, elements, or components, but do not preclude the presence or addition of one or more other features, integers, steps, operations, elements, components, or groups thereof. Moreover, it is understood that the word “or” has the same meaning as the Boolean operator “OR,” that is, it encompasses the possibilities of “either” and “both” and is not limited to “exclusive or” (“XOR”), unless expressly stated otherwise. It is also understood that the symbol “/” between two adjacent words has the same meaning as “or” unless expressly stated otherwise. Moreover, phrases such as “connected to,” “coupled to” or “in communication with” are not limited to direct connections unless expressly stated otherwise.

If used herein, the term “determining” encompasses a wide variety of actions. For example, “determining” may include calculating, computing, processing, deriving, investigating, looking up (e.g., looking up in a table, a database or another data structure), ascertaining, and the like. Also, “determining” may include receiving (e.g., receiving information), accessing (e.g., accessing data in a memory), and the like. Also, “determining” may include resolving, selecting, choosing, establishing, and the like.

Any reference to an element herein using a designation such as “first,” “second,” and so forth does not generally limit the quantity or order of those elements. Rather, these designations may be used herein as a convenient method of distinguishing between two or more elements or instances of an element. Thus, a reference to first and second elements does not mean that only two elements may be used there or that the first element must precede the second element in some manner. Also, unless stated otherwise a set of elements may include one or more elements. In addition, terminology of the form “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As a further example, “at least one of: A, B, or C” is intended to cover A, B, C, A-B, A-C, B-C, and A-B-C, as well as multiples of the same members (e.g., any lists that include AA, BB, or CC). Likewise, “at least one of: A, B, and C” is intended to cover A, B, C, A-B, A-C, B-C, and A-B-C, as well as multiples of the same members. Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A structure for use in a disk drive, the structure comprising:
a substrate of a component of the disk drive;
a diamond-like carbon (DLC) film on the substrate;
a buffer layer on the DLC film; and
an oxide layer on the buffer layer.

2. The structure of claim 1, wherein the oxide layer comprises an oxide selected from a group consisting of hafnium dioxide, tantalum pentoxide, yttrium-doped zinc oxide (YZO), yttrium-stabilized zirconia (YSZ), zirconium oxide (ZrOₓ), titanium oxide (TiOₓ), and combinations thereof.

3. The structure of claim 1, wherein the oxide layer has a thickness of at least 1.5 nm.

4. The structure of claim 1, wherein the oxide layer is configured to reduce one or more of a temperature-based oxidation of the DLC film, a temperature-based loss of optical transparency in the DLC film, and a temperature-based loss of thermal stability of the DLC film as compared to a corresponding structure without the oxide layer.

5. The structure of claim 1, wherein the buffer layer comprises a compound selected from a group consisting of silicon nitride (S₃N₄), titanium nitride (TiNₓ), titanium oxynitride (TiNₓO₁₋ₓ), chromium nitride (CrNₓ), chromium oxynitride (CrNₓO₁₋ₓ), nickel chromium (NiCr), silicon carbide (SiC), and combinations thereof.

6. The structure of claim 1, wherein the buffer layer has a thickness of at least 0.5 nanometers (nm).

7. The structure of claim 1, wherein the buffer layer is configured to reduce an amount of chemical mixing between the oxide layer and the DLC film as compared to a corresponding structure without the buffer layer.

8. The structure of claim 1, wherein the DLC film has a thickness of no more than 3.0 nanometers (nm).

9. The structure of claim 1, wherein the substrate comprises a metal alloy.

10. The structure of claim 1, wherein the component comprises a slider of the disk drive and the substrate comprises a portion of a slider.

11. A disk drive comprising the structure of claim 10.

12. A method for forming a structure for use in a disk drive, the method comprising:
providing a component of the disk drive, where the component comprises a substrate;
forming a diamond-like carbon (DLC) film on the substrate;
forming a buffer layer on the DLC film; and
forming an oxide layer on the buffer layer.

13. The method of claim 12, wherein the oxide layer is formed using an oxide selected from a group consisting of hafnium dioxide, tantalum pentoxide, yttrium-doped zinc oxide (YZO), yttrium-stabilized zirconia (YSZ), zirconium oxide (ZrOₓ), titanium oxide (TiOₓ), and combinations thereof.

14. The method of claim 12, wherein the oxide layer is formed with a thickness of at least 1.5 nm.

15. The method of claim 12, wherein the buffer layer is formed using a compound selected from a group consisting of silicon nitride (S₃N₄), titanium nitride (TiNₓ), titanium oxynitride (TiNₓO₁₋ₓ), chromium nitride (CrNₓ), chromium oxynitride (CrNₓO₁₋ₓ), nickel chromium (NiCr), silicon carbide (SiC), and combinations thereof.

16. The method of claim 12, wherein the buffer layer is formed with a thickness of at least 0.5 nanometers (nm).

17. The method of claim 12, wherein the DLC film is formed with a thickness of no more than 3.0 nanometers (nm).

18. The method of claim 12, wherein the substrate comprises a portion of a slider and wherein the DLC film is formed on the slider.

19. The method of claim 12, wherein the substrate comprises a portion of a slider having a waveguide and wherein the DLC film is formed over an end of the waveguide.

20. A structure for use in a disk drive, the structure comprising:
a substrate of a component of the disk drive;
a diamond-like carbon (DLC) film on the substrate; and
a silicon nitride layer on the DLC film.

21. The structure of claim 20, wherein the silicon nitride layer has a thickness of at least 2.0 nanometers (nm).

22. The structure of claim 20, wherein the silicon nitride layer is configured to reduce one or more of a temperature-based oxidation of the DLC film, a loss of temperature-based optical transparency in the DLC film, and a loss of thermal stability of the DLC film as compared to a corresponding structure without the silicon nitride layer.

23. The structure of claim 20, wherein the DLC layer has a thickness of no more than 3.0 nanometers (nm).

24. The structure of claim 20, wherein the component comprises a slider of the disk drive and the substrate comprises a portion of a slider.

25. A disk drive comprising the structure of claim 24.

26. A method for forming a structure for use in a disk drive, the method comprising:
providing a component of the disk drive, where the component comprises a substrate;
forming a diamond-like carbon (DLC) film on the substrate; and
forming a silicon nitride layer on the DLC film.

27. The method of claim 26, wherein the silicon nitride layer is formed with a thickness of at least 2.0 nanometers (nm).

28. The method of claim 26, wherein the DLC film is formed with a thickness of no more than 3.0 nanometers (nm).

29. The method of claim 26, wherein the substrate comprises a portion of a slider and wherein the DLC film is formed on the slider.

30. The method of claim 26, wherein the substrate comprises a portion of a slider having a waveguide and wherein the DLC film is formed over an end of the waveguide.
